(19) United States
(12) Patent Application Publication
(10) Pub. No.: US 2011/0175408 A1
(43) Pub. Date: Jul. 21, 2011

(54) DOCKING SYSTEM

(76) Inventors: Nick Ridler, Warwickshire (GB); Peter Thomas, Leicestershire (GB); Duncan Robertson, Warwickshire (GB)

(21) Appl. No.: 13/003,338

(22) PCT Filed: Jul. 9, 2009
(86) PCT No.: PCT/IB2009/052995

§ 371 Date: Apr. 8, 2011

(30) Foreign Application Priority Data
Jul. 10, 2008 (GB) 0812557.7

(51) Int. Cl. B60R 11/02; H05K 5/00

(52) U.S. Cl. 297/188.16; 361/679.01

(57) ABSTRACT

A docking system 10 having; a housing 14 and a support element 30 pivotally mounted with respect to the housing 14, an attachment mechanism 40,44 being provided on said support element 30 for releasably securing a remote control 12, the support element 30 being movable between a first position in which the remote control 12 mounted on the support element 30 would be contained within the housing 14 and a second position in which the remote control 12 mounted on the support element 30 would extend from the housing 14 and may be released from the support element 30. The support element 30 is resiliently biased towards the second position, latch means 36, 38 being provided to releasably retain the support element 30 in the first position and electrical contacts being provided for engagement of corresponding electrical contacts on an electrical device mounted on the support element 30.

The present invention relates to a docking system for recharging electrical devices, for example remote controls for entertainment or navigation systems, mobile telephones, MP3 players and the like or any combination of such devices. The docking system is particularly suitable for use in motor vehicles. The docking system may however be used in other applications.

According to a first aspect of the invention there is provided a docking system mounted in a compartment of an armrest or a console of a motor vehicle comprising; a housing being in the form of a tray having a base and sidewalls, the tray being shaped to conform to the shape of an electrical device which is to be used with the docking system, an attachment mechanism for releasably securing the electrical device within the housing, and electrical contacts being provided for engagement of corresponding electrical contacts on an electrical device.

The docking system may further comprise a support element pivotally mounted with respect to the housing, the attachment mechanism being provided on said support element for releasably securing the electrical device, the support element being movable between a first position in which the electrical device mounted on the support element would be contained within the housing and a second position in which the electrical device mounted on the support element would extend from the housing and may be released from the support element, the support element being resiliently biased towards the second position, latch means being provided to releasably retain the support element in the first position and electrical contacts being provided for engagement of corresponding electrical contacts on an electrical device mounted on the support element.

According to a second aspect of the invention there is provided an electrical device for use with a docking system according to the first aspect of the invention.

Preferably, the electrical device is a remote control for an entertainment system or navigation system, a mobile telephone, a MP3 player or any combination of such devices.

According to a third aspect of the invention there is provided a seat arm rest of a motor vehicle comprising a body, a compartment in said body and a lid mounted on said body which covers the compartment wherein said compartment is provided with a docking system for an electrical device, the docking system comprising a housing mounted in the compartment, an attachment mechanism for releasably securing an electrical device, and electrical contacts being provided for engagement of corresponding electrical contacts on an electrical device.

The invention will now be described by way of example with reference to the accompanying drawings of which:

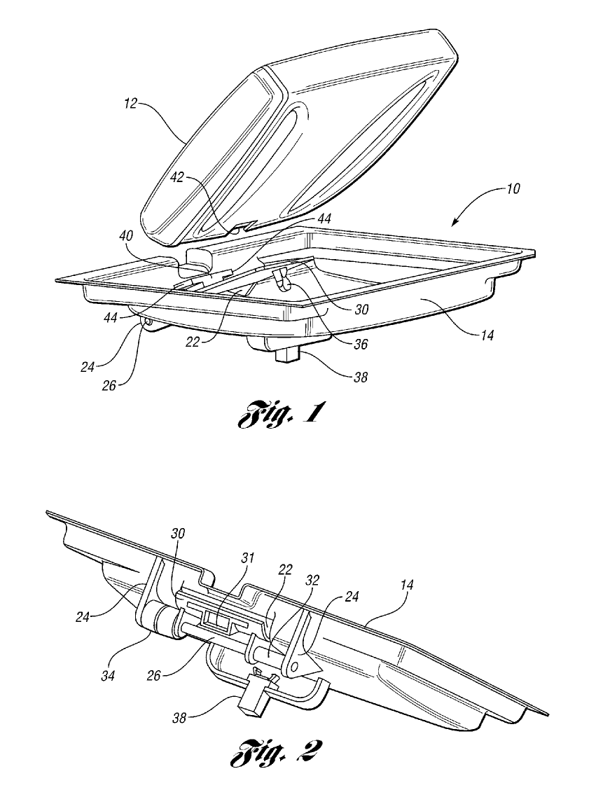

FIG. 1 is a perspective view from the front, side and above, of a docking station in accordance with the present invention, showing a remote control for an in car entertainment system;

FIG. 2 is a perspective view of the docking system illustrated in FIG. 1, from the rear, side and below;

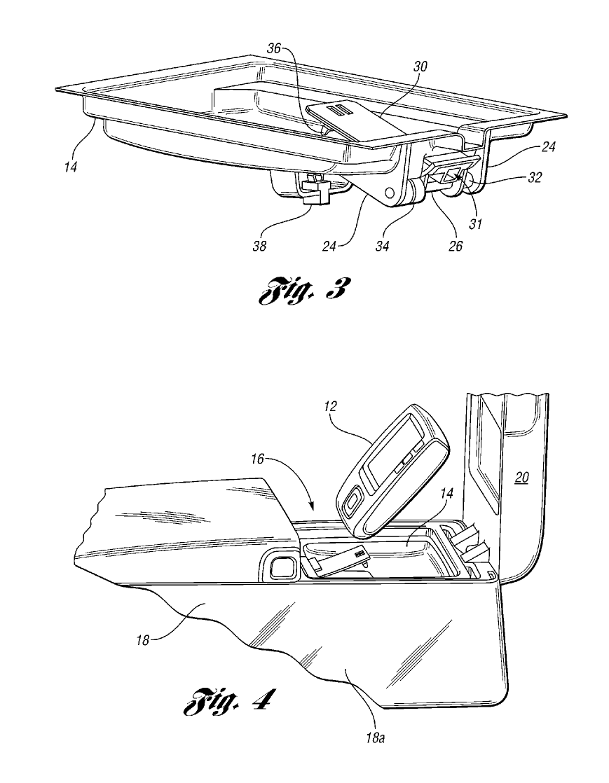

FIG. 3 is a perspective view of the docking system illustrated in FIG. 1, from the rear, side and above; and

FIG. 4 is a perspective view from the side and above, of the docking system illustrated in FIG. 1, mounted in a rear seat arm rest of a vehicle.

As illustrated in the accompanying drawings, a docking system 10 for a remote control 12 of an in car entertainment system has a housing 14 in the form of a tray, having a base and sidewalls, which is moulded from plastics material. The internal dimensions of the tray conform to the shape of the remote control 12. As illustrated in FIG. 4, the housing 14 is adapted to be secured in a compartment 16 in a rear seat arm rest 18 of a motor vehicle. The arm rest, in a well-known manner, has a body 18a which is pivotally supported at a vehicle seat (not shown) for movement between a stowed closed position (not shown) and a passenger access position (FIG. 4). As can best be seen in FIG. 4, a hinged lid 20 is mounted on the body 18a and arranged in such a way that in its closed position the lid 20 covers the compartment 16.

An aperture 22 is provided in the base of the housing 14 towards the rear edge thereof and a pair of lug formations 24 formed integrally of the housing 14 extend to the rear side of the base of the housing, on either side of the aperture 22. A pivot pin 26 is mounted between the lug formations 24. A support element or carrier arm 30 is pivotally mounted on the pivot pin 26 and extends through the aperture 22 into the housing 14 and towards the front edge of the housing 14. Hence the carrier arm is movable between a first position or storage position and a second position or open position as it will be further explained.

Stop means in the form of an abutment surface 31 extending from the carrier arm 30 is provided to limit movement of the carrier arm 30 in its open position. This abutment surface 31 abuts the pivot pin 26 when the carrier arm 30 is away from the base of the housing 14, as can be seen FIG. 3.

A torsion spring 32 is mounted on the pivot pin 26 and acts on the carrier arm 30 to bias the portion of the carrier arm 30 disposed within the housing 14, away from the base of the housing 14, so that the carrier arm 30 will be inclined upwardly from the base of the housing 14, from rear to front.

A damper assembly 34, which may be of conventional design, for example of the type used on grab handles for motor vehicles, in which a pair of concentric cylindrical plastic elements are mounted one inside the other, the outer cylindrical surface of the inner element frictionally engaging the inner cylindrical surface of the outer element. The cylindrical elements are mounted on the pivot pin 26, the inner element being constrained to rotate with the carrier arm 30 and the outer element being fixed rotationally with respect to the housing 14, so that the damper assembly 34 will apply a frictional damping force, resisting movement of the carrier arm 30.

The carrier arm is releasably retained in its first position by a latch means having in this example a detent 36 and a spring loaded catch assembly 38. The detent 36 is provided on the underside of the carrier arm 30. The detent 36 extends through an aperture in the base of the housing 14 when the carrier arm 30 is depressed against the force applied by the torsion spring 32. The catch assembly 38 is provided on the rear side of the base of the housing 14 and is engaged by the detent 36 to retain the carrier arm 30 in a depressed position, in which it is disposed substantially parallel to the base of the housing 14 in juxtaposed relationship thereto. The catch assembly 38 may be of known design whereby the detent 36 may be released from the catch assembly by pushing the carrier arm 30 towards the catch assembly 38 and then releasing the carrier arm 30, so that it pivots upwardly under the force applied by torsion spring 32 under the control of the damper assembly 34.

The carrier arm 30 is also provided with an attachment mechanism for releasably secure the remote control. The attachment mechanism has a T-shaped slide formation 40 moulded to the upper face thereof, adjacent the rear of the housing 14. The T-shaped slide formation 40 corresponds to a longitudinally extending aperture 42 in the remote control 12, the aperture 42 having flange formations which engage between the upper face of the carrier arm 30 and flange formations 44 defined by the T-shaped slide formation 40, to slidably retain the remote control 12 on the carrier arm 30.

Electrical contacts (not shown) are mounted on the upper surface of the T-shaped slide formation 40 and are connected to a charging circuit itself connected to a power supply. The electrical contacts are adapted to engage a pair of spring loaded contacts provided in the aperture 42 of the remote control 12, when the remote control 12 is mounted on the carrier arm 30, thereby connecting the remote control 12 to the power supply, for recharging.

With the docking station 10 described above, when the detent 36 is released from the catch assembly 38, the torsion spring 32 will cause the carrier arm 30 to be disposed in an open position in which it is inclined upwardly from the pivot pin 26. In this open position, the aperture 42 in the remote control 12 may be engaged with the T-shaped slide formation 40 on the carrier arm 30 to retain the remote control 12 on the carrier arm 30 and make connection between the electrical contacts in the carrier arm 30 and the remote control 12. The remote control 12 on the carrier arm 30 may then be pressed down into the housing 14 and retained in a storage position, by engagement of the detent 36 by the catch assembly 38. The lid 20 of the compartment 16 may then be closed and the arm rest 18 may be pivoted towards its stowed closed position.

In order to release the remote control 12 for use, the remote control 12 on the carrier arm 30 is pressed down to release the detent 36 from the catch assembly 38, so that the spring 32 will return the carrier arm 30 to the open position under control of the damper assembly 34. The remote control 12 may then be removed from the carrier arm 30 or be left in this upward position to control the entertainment system, the radio, the navigation system, the mobile phone and the like or any of such combination.

It will be appreciated that various modifications can be made to the docking system described above. For example, the docking system may be mounted in central console of the vehicle. Alternatively, the attachment mechanism described above could be replaced by clip means for engagement of the remote control. According to another alternative, the support element is removed from the housing. In this case, electrical contacts are mounted on one of the sidewalls of the housing and remote control is locked in position within the housing by a attachment mechanism having a detent provided on the underside of the remote control which is engageable with the spring loaded catch assembly. It will be appreciated that locating features may also be provided on one of the sidewalls of the housing to locate the remote control correctly within the housing.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

1. A docking system mounted in a compartment of an armrest or a console of a motor vehicle comprising; a housing being in the form of a tray having a base and sidewalls, the tray being shaped to conform to the shape of an electrical device which is to be used with the docking system, an attachment mechanism for releasably securing the electrical device within the housing, and electrical contacts being provided for engagement of corresponding electrical contacts on an electrical device.

2. A docking system according to claim 1 which further comprises a support element pivotally mounted with respect to the housing, the attachment mechanism being provided on said support element for releasably securing the electrical device, the support element being movable between a first position in which the electrical device mounted on the support element would be contained within the housing and a second position in which the electrical device mounted on the support element would extend from the housing and may be released from the support element, the support element being resiliently biased towards the second position, latch means being provided to releasably retain the support element in the first position and electrical contacts being provided for engagement of corresponding electrical contacts on an electrical device mounted on the support element.

3. A docking system according to claim 1 in which the housing has a hinged lid.

4. A docking system according claim 1 in which the support element is mounted on a pivot located externally of the housing, the support element extending from the pivot through an aperture in the housing.

5. A docking system according to claim 4 in which the support element is pivoted adjacent one wall of the housing, below a base of the housing, the support element in its second position; being inclined upwardly from the pivot towards an opposite wall of the housing; and in its first position being substantially parallel to the base of the housing, in juxtaposed relationship thereto.

6. A docking system according to claim 2 in which interengaging slide formations are provided on the support element and electrical device, so that the electrical device may be located and retained on the support element.

7. A docking system according to claim 6 in which the support element has a T-shaped slide formation for engagement of flange formations on the electrical device.

8. A docking system according to claim 2 in which the support element is provided with clip means for engagement of the electrical device.

9. A docking system according to claim 2 in which a detent is provided on the support element for engagement of a catch assembly mounted on the housing.

10. A docking system according to claim 9 in which the detent is provided on the rear side of the support element, so that it extends in the direction of a base of the housing, a catch assembly being secured to the base of the housing for engagement of the detent, when the support element is in its first position.

11. A docking system according to claim 11, in which the detent is released from the catch assembly by depressing the support element towards the catch assembly.

12. A docking system according to claim 2 in which damping means is provided to control movement of the support element from the first position to the second position, following release of the latch means.

13. A docking system according to claim 1 in which the electrical contacts are connected to a charging circuit.

14. An electrical device for use with a docking system as claimed in claim 2, in which the electrical device is provided with formations for engagement with corresponding formations on the support element of the docking system.

15. An electrical device for use with a docking system as claimed in claim 1 in which the electrical device is provided with a detent is provided on the electrical device for engagement of a catch assembly mounted on the housing.

16. An electrical device according to claim 15 in which the electrical device is a remote control for an entertainment or navigation system, a mobile telephone, a MP3 player or any combination of such devices.

17. A seat arm rest of a motor vehicle comprising a body, a compartment in said body and a lid mounted on said body which covers the compartment wherein said compartment is provided with a docking system for an electrical device, the docking system comprising a housing mounted in the compartment, an attachment mechanism for releasably securing an electrical device, and electrical contacts being provided for engagement of corresponding electrical contacts on an electrical device.

18. A seat arm rest according to claim 18 which further comprises a support element pivotally mounted with respect to the housing, the attachment mechanism being provided on said support element for releasably securing the electrical device, the support element being movable between a first position in which the electrical device mounted on the support element would be contained within the housing and a second position in which the electrical device mounted on the support element would extend from the housing and may be released from the support element, the support element being resiliently biased towards the second position, latch means being provided to releasably retain the support element in the first position and electrical contacts being provided for engagement of corresponding electrical contacts on an electrical device mounted on the support element.

19. A seat arm rest according to claim 18, wherein said body is pivotally supported at a vehicle seat for movement between a stowed closed position and a passenger access position.

20. A seat arm rest according to claim 18, in which the electrical device is a remote control for an entertainment or navigation system, a mobile telephone, a MP3 player or any combination of such devices.
